(19) United States
(12) Patent Application Publication
(10) Pub. No.: US 2010/0025019 A1
(43) Pub. Date: Feb. 4, 2010

(54) HEAT EXCHANGER FOR COOLING SEMICONDUCTOR CHIP AND METHOD OF MANUFACTURING THE SAME

(76) Inventors: Hitoshi Sakamoto, Tokyo (JP); Kazuyuki Mikubo, Tokyo (JP); Sakae Kitajo, Tokyo (JP)

Correspondence Address: Mr. Jackson Chen, 6535 N. STATE HWY 161, IRVING, TX, 75039, US

(21) Appl. No.: 12/518,357

(22) PCT Filed: Dec. 3, 2007
(86) PCT No.: PCT/JP2007/001339

§ 371 Date: Jun. 9, 2009

(30) Foreign Application Priority Data
Dec. 18, 2006 (JP) 2006-340007

(51) Int. Cl. H01L 23/34; F28D 15/00; F28F 13/00; B21D 53/02

(52) U.S. Cl. 165/104.33; 29/890.03

(57) ABSTRACT

Behavior of a vapor bubble that emerges should be controlled to improve operational stability and reliability of a phase shift heat exchanger having a microchannel. The heat exchanger has a dual layer structure and includes a material that is elastically deformed according to pressure difference between the layers. The layers are connected, and at the connection interface a resistance unit that exerts a predetermined resistance against a coolant flowing from the coolant supplying layer toward the microchannel layer is provided, to maintain internal pressure of the coolant supplying layer higher than that of the microchannel, under a normal operation. Once a vapor bubble emerges, the relationship in strength of the internal pressure is turned over, and the elastic material is lifted so that the vapor bubble is dividedly distributed over a plurality of microchannels. Alternatively, the internal pressure of the coolant supplying layer may be maintained lower than that of the microchannel, so that once a vapor bubble emerges the vapor bubble is drawn to the lower pressure side.

### TECHNICAL FIELD

The present invention relates to a heat exchanger that utilizes a microchannel and a boiling phenomenon for cooling a semiconductor, and to a method of manufacturing such heat exchanger.

### BACKGROUND ART

A technique has been developed for transferring a large amount of heat generated by a semiconductor, which includes adhering a material having high thermal conductivity to an external portion of the semiconductor, and forming a microchannel of several hundred microns or less in diameter to thereby execute liquid cooling.

Lately, studies are being made on the technique of utilizing a coolant flowing in the channel at a temperature close to the boiling point to thereby utilize the heat of vaporization of the coolant, thus achieving a higher heat transfer effect.

Although the detailed mechanism of the improvement in heat transfer performance by boiling has not yet been elucidated, it is a common knowledge that, for example in a steam generator, the heat transfer coefficient becomes lower with an increase in dryness of the vapor.

Assumingly this is because the contact surface between the inner wall of the channel, which serves as the heat transfer surface, and the coolant in the gas phase becomes larger along the flow direction. Generally the heat transfer performance to a gas phase is lower than that to a liquid phase, and hence naturally improvement in heat transfer performance cannot be expected, by the phase shift from the liquid phase to the gas phase.

Feasible methods of separating produced bubbles from the heat generating surface and eliminating the bubbles from inside the channel as quickly as possible include increasing the flow speed of the coolant to thereby forcibly sweep away the bubbles, applying a surface treatment to the inner wall of the channel so as to suppress the emergence of the bubbles, and connecting the channels so as to intersect to thereby minimize pressure difference among the channels (Ref. Patent document 1, for example). These are, however, just passive methods which incur a compromise in performance of the microchannel.

For the purpose of cooling a semiconductor, an invention of a more compact and positive mechanism for eliminating the boiling bubble is desired.

[Patent document 1] JP-A No. 2001-28415

### DISCLOSURE OF THE INVENTION

### Problem to be Solved by the Invention

Despite the attempt to improve the heat transfer characteristic of a heat exchanger having a fine channel, generally called a microchannel, utilizing heat of vaporization available from boiling, obtaining a higher boiling effect leads to increased dryness of the vapor on a downstream side of the channel, and also to quicker growth in size of a boiling bubble to such extent as occupying the entire width of the channel, and such states incur various disadvantages.

In the microchannel, provided for the purpose of maximizing the contact surface with a coolant, it is by no means easy to control the behavior of the vapor bubbles that emerge, and therefore the location, frequency and pattern of emergence, the growing speed, the departing or residing movement and so on of the bubble are different among the channels and depending on the condition of each individual channel. In an extreme case, local decline in heat transfer performance or local increase in temperature may take place, thereby degrading the performance of the heat exchanger expected from its spec.

In a heat exchanger that includes a plurality of microchannels, the channels are often spaced from each other, and in such case the emerging pattern and residing behavior of the bubbles may be different in each channel, which may even incur difference in pressure distribution, flow rate and heat transfer performance.

Unbalanced growth of the bubbles provokes abrupt growth thereof, and in the channel where such phenomenon takes place the coolant may flow backward, to thereby temporarily increase the flow rate in a channel where the coolant is not yet boiled. The increase in flow rate may further suppress the boiling thus producing a vicious circle, and the unbalance in flow rate and boiling status among the channels is further expanded. Moreover, because of the fine size of the channel, the drawback of superheating, that the boiling bubble does not emerge despite reaching the boiling point, has also been observed.

The amount of the boiling bubbles that should be produced may be substantially different depending on the heat transfer amount, within the rated performance of the heat exchanger, and therefore the behavior of the boiling bubbles has to be controlled so as not to provoke unfavorable effect, under any operational condition.

To make the most of the effect of the phase shift, it may be appropriate to increase the dryness of the vapor at the outlet of the heat exchanger, however it is known that the increase in dryness results in decline in heat transfer coefficient. Although improving the heat transfer efficiency with the heat fluctuation is an attractive technique that enables reducing the pump capacity, since the bubbles themselves that emerge do not contribute to improving the heat transfer effect, it is necessary to effectively separate the bubbles from the heat generating surface, and discharge out of the channel.

The present invention has been accomplished under the foregoing situation, and provides a phase-shift heat exchanger including a microchannel that enables controlling the behavior of the boiling bubbles that emerge, to thereby improve the stability in operation and reliability of the heat exchanger, and a method of manufacturing such heat exchanger.

### Means for Solving Problem

The present invention provides mechanisms that allow positively controlling a behavior of a boiling bubble in a microchannel. A first mechanism includes a flow path built in a dual layer form, and employs a material that can be elastically deformed according to a pressure difference between the layers. In a second mechanism the layers are connected to each other, and at the connection interface a resistance unit that exerts a predetermined resistance (pore or barrier wall) against a coolant flowing from the layer that supplies the coolant toward the layer that includes the microchannel is provided, so as to maintain an internal pressure of the coolant supplying layer higher than that of the microchannel. In a third mechanism, the layers are connected as in the second mechanism, however the internal pressure of the coolant supplying layer is maintained lower than that in the microchannel. These mechanisms are optimized upon being employed independently or in combination.

The present invention enables minimizing over a more extensive range the unfavorable influence of massive emergence of the vapor bubbles, thereby contributing not only to improving the heat transfer performance by maintaining a high heat transfer coefficient, but also to eliminating residual bubbles and suppressing superheating, thus stabilizing the operation of the heat exchanger with the microchannel as a whole.

The mechanism incorporated in the heat exchanger positively copes with the bubbles that irregularly emerge, so as to minimize the risk of emergence of a bubble that explosively grows, and to thereby suppress the backward flow of the coolant.

With the first mechanism, during normal operation (stabilized operation) the internal pressure of the coolant supplying layer is higher than that of the microchannel layer, however once a vapor bubble emerges in the microchannel, the relationship in strength of the internal pressure is turned over. In response to such pressure fluctuation inside the microchannel located in the microchannel layer, the elastic material provided as the partition that defines the coolant supplying layer moves up and down.

Such upward movement of the elastic material due to the emergence of the vapor bubble provides the same effect as the state that the partition between the microchannel in which the pressure has increased and an adjacent microchannel is removed, and hence the increased pressure can be dispersed over a plurality of microchannels, and in the case where a bubble that has grown large is present, such bubble can be divided by the adjacent microchannels and flushed away to the downstream side.

The pressure on the back of the elastic material is substantially equal to that in the upstream portion of the microchannel, so that while the pressure in the microchannel is stabilized the pressure on the back of the elastic material is greater than that in the microchannel, and hence the elastic material is pressed against the upper face of the microchannel to thereby isolate the microchannels.

The second mechanism generates a secondary flow in the microchannel, to thereby efficiently discharge the vapor bubble about to reside. Since the internal pressure of the coolant supplying layer is maintained higher than that of the microchannel layer, providing a nozzle on the partition hat divides the two layers connected to each other permits a part of the coolant to flow from the coolant supplying layer into the microchannel layer, through the nozzle.

Therefore, orienting the nozzle in the forward direction of the flow of the coolant into the microchannel enables increasing the flow speed of the coolant through the microchannel with the coolant flowing in through the nozzle. The accelerated flow of the coolant rapidly flushes the vapor bubble that may have emerged toward the outlet, thus discharging the same.

In general, a coolant of a liquid phase has higher viscosity than the coolant of the same substance of a gas phase, and provides the advantage of enabling the nozzle to selectively discharge the vapor bubble. Besides, in the case where the vapor bubble abruptly grows, the pressure inside the bubble temporarily becomes greater than the pressure of the ambient liquid, and therefore the bubble can be selectively discharged.

The third mechanism maintains the internal pressure of the coolant supplying layer lower than that of the microchannel, so that the vapor bubble that has emerged in the microchannel is drawn into the coolant supplying layer, thus to be efficiently discharged.

Thus, according to the present invention there is provided a heat exchanger to be used for cooling a semiconductor chip, comprising a first layer including a plurality of microchannels through which a coolant flows, a second layer provided adjacent to the first layer, and including a supply path through which the coolant is supplied to the microchannel, and a resistance unit that resists against a flow of the coolant from the supply path into the microchannel, wherein a partition between the first layer and the second layer is constituted essentially of an elastic material (first and second mechanism).

According to the present invention there is provided another heat exchanger comprising a third layer including a plurality of microchannels through which a coolant flows, a fourth layer provided adjacent to the third layer, and including a supply path through which the coolant is supplied to the microchannel, and a nozzle that generates a leak flow of the coolant in a direction to accelerate a flow speed of the coolant through the microchannel (second mechanism).

According to the present invention there is provided another heat exchanger comprising a fifth layer including a plurality of microchannels through which a coolant flows, a sixth layer provided adjacent to the fifth layer, and from which a part of the coolant supplied to the microchannel flows out, and a hole that allows the part of the coolant supplied to the microchannel to flow into the sixth layer (third mechanism).

The present invention can also be defined from the viewpoint of a manufacturing method of the heat exchanger. In this case, according to the present invention there is provided a method of manufacturing a heat exchanger to be used for cooling a semiconductor chip, comprising forming a first layer including a plurality of microchannels through which a coolant flows, forming a second layer adjacent to the first layer, so as to include a supply path through which the coolant is supplied to the microchannel, forming a resistance unit that resists against a flow of the coolant from the supply path into the microchannel, and forming a partition between the first layer and the second layer with an elastic material (first and second mechanism).

According to the present invention there is provided another method of manufacturing a heat exchanger, comprising forming a third layer including a plurality of microchannels through which a coolant flows, forming a fourth layer adjacent to the third layer, so as to include a supply path through which the coolant is supplied to the microchannel, and forming a nozzle that generates a leak flow of the coolant in a direction to accelerate a flow speed of the coolant through the microchannel (second mechanism).

According to the present invention there is provided another method of manufacturing a heat exchanger, comprising forming a fifth layer including a plurality of microchannels through which a coolant flows, forming a sixth layer adjacent to the fifth layer, such that a part of the coolant supplied to the microchannel flows out of the sixth layer, and forming a hole that allows the part of the coolant supplied to the microchannel to flow into the sixth layer (third mechanism).

### ADVANTAGE OF THE INVENTION

A first advantageous effect of the present invention originates from the mechanism that can positively divide and remove a vapor bubble through the microchannel, thereby inhibiting the bubble from residing and disturbing the heat transfer performance.

A second advantageous effect of the present invention originates from the structure that can maintain the pressure balance between the microchannels in the heat exchanger including a plurality of microchannels, so that the coolant is uniformly boiled in each microchannel, and that the heat exchanger gains higher stability and reliability.

A third advantageous effect of the present invention is that the dual layer structure allows the upper layer itself to serve as a manifold, and that therefore the foregoing advantages can be attained without increasing the footprint of the heat exchanger compared with a conventional model.

### BRIEF DESCRIPTION OF THE DRAWINGS

The above and other objects, features and advantages of the present invention will become more apparent through the description of the preferred embodiments given below, and the accompanying drawings described as follows.

FIG. 1 includes cross-sectional views showing a structure of a heat exchanger according to a first embodiment;

FIG. 2 includes cross-sectional views showing the state that a vapor bubble has emerged in the heat exchanger according to the first embodiment;

FIG. 3 includes cross-sectional views showing a structure of a heat exchanger according to a second embodiment; and

FIG. 4 includes cross-sectional views showing a structure of a heat exchanger according to a fourth embodiment.

### BEST MODE TO CARRY OUT THE INVENTION

The embodiments of the present invention will be described in details hereunder, referring to the drawings.

### First Embodiment

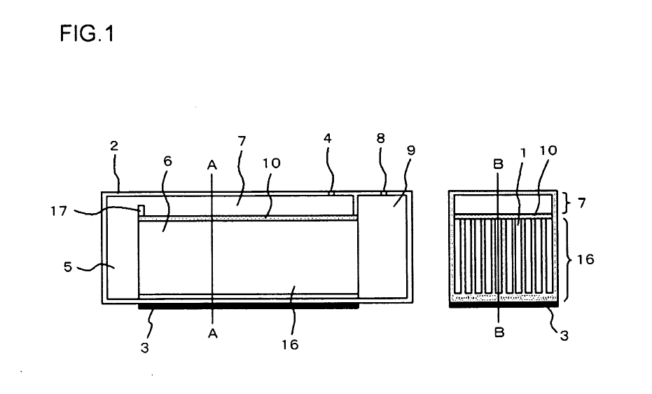

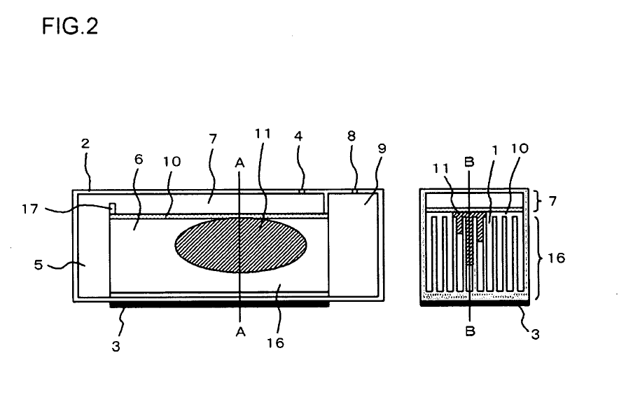

A first embodiment of the present invention will be described, referring to FIGS. 1 and 2. FIG. 1 depicts a dual layer heat exchanger including a partition that can be elastically deformed according to the pressure of the two layers. The heat exchanger includes a coolant retention layer 7 in an upper portion, and in a lower portion a heat receiving layer 16 including a microchannel 1.

At the connection interface between the coolant retention layer 7 and the heat receiving layer 16, a barrier wall 17 is provided so as to serve as a resistance against the flow of a coolant, supplied into the coolant retention layer 7 through a fluid inlet 4 so as to flow into the heat receiving layer 16. Accordingly, the flow speed in the coolant retention layer 7 is slower than in the heat receiving layer 16, and the pressure in the coolant retention layer 7 is higher than that in the heat receiving layer 16. Also, the fluid inlet 4 may be located above the coolant retention layer 7, which enables reducing the size of an inlet manifold 5. Another feature is that an elastic material, which serves as an elastic partition 10, is provided between the layers.

Examples of the elastic material include silicone-based and acrylic-based rubbers. Alternatively, it is also effective to employ a metal material having low elasticity as the partition itself, and apply the foregoing rubber material to the upper portion of the metal partition. In either case, the up and downward movement of the partition according to a pressure increase in the heat receiving layer contributes to leveling off a pressure difference between adjacent channels.

FIG. 2 depicts the state that a vapor bubble 11 has emerged in the microchannel 1 in the heat receiving layer 16. During normal operation (stabilized operation) the internal pressure of the coolant retention layer 7 is higher than that of the heat receiving layer 16, and hence the elastic partition 10 performs the function of isolating the plurality of microchannels 1 from each other, however in case where the pressure in the microchannel 1 locally rises because of the vapor bubble 11 shown in FIG. 2, the elastic partition 10 moves upward owing to the pressure difference between the coolant retention layer 7 and the heat receiving layer 16, to thereby release the adjacent microchannels 1 from isolation from one another, thus restoring the pressure balance among the microchannels 1. At the same time, the vapor bubble 11 which has grown is dividedly distributed to the adjacent microchannels 1 and discharged, thus being inhibited from residing in the microchannel 1 which is the source of the vapor bubble 11.

### Second Embodiment

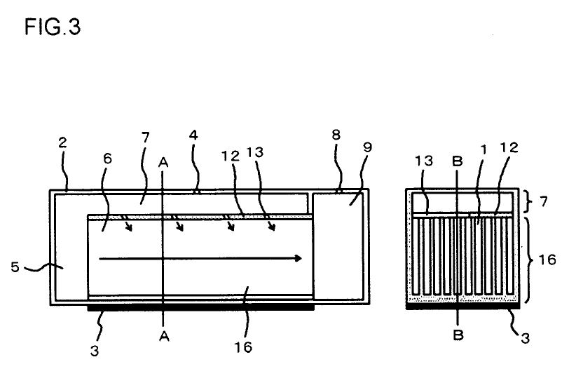

A second embodiment of the present invention will be described referring to FIG. 3. FIG. 3 depicts a dual layer heat exchanger according to the second embodiment of the present invention, which causes the coolant to leak from the coolant retention layer 7 to the heat receiving layer 16, to thereby provoke a secondary flow in the heat receiving layer 16. In this embodiment, a non-elastic partition 12 is employed as the partition. The nozzle 13, constituting the novel feature of this embodiment and which provokes the secondary flow, is oriented at a predetermined angle in a forward direction with respect to the flow of the coolant through the microchannel 1, so as to effectively provoke the secondary flow.

Under such configuration, the leak flow which flows from the coolant retention layer 7 into the heat receiving layer 16 through the nozzle 13 provokes the secondary flow in the heat receiving layer 16, thereby serving to quickly flush the vapor bubble toward an outlet manifold 9, utilizing the accelerated flow produced in the heat receiving layer 16.

### Third Embodiment

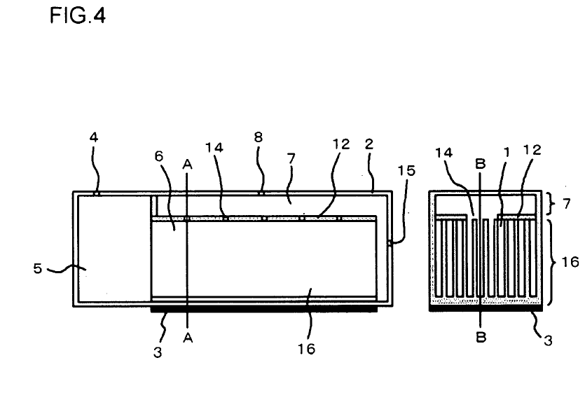

A third embodiment of the present invention will be described referring to FIG. 4. FIG. 4 depicts a dual layer heat exchanger according to the third embodiment of the present invention, including a mechanism in which a saturated fluid outlet 15 and a vapor outlet 8 are provided apart from each other. In this embodiment, although the advantage of reducing the size of the inlet manifold 5 compared with a conventional model cannot be attained because the fluid inlet 4 is located on the inlet manifold 5, a heat exchanger block 2 can also serve as a gas-liquid separation mechanism, which facilitates reducing the footprint of the heat exchanger compared with a conventional model.

The coolant supplied through the fluid inlet 4 is directly supplied to the heat receiving layer 16. The coolant in its liquid phase flows from the heat receiving layer 16 into the coolant retention layer 7 through a pore 14. Since the pore 14 acts as a resistance against the flow of the coolant, the internal pressure of the coolant retention layer 7 becomes lower than that of the heat receiving layer 16. Accordingly, a vapor bubble that has grown in an upper portion of the microchannel 1 is taken up into the coolant retention layer 7 through the pore 14, because of the pressure difference.

Further, providing the vapor outlet 8 and the saturated fluid outlet 15 enables distinctively utilizing the vapor outlet 8 as the outlet of the vapor having high dryness, and the saturated fluid outlet 15 as the outlet of the saturated fluid having low dryness.

### INDUSTRIAL APPLICABILITY

Application examples of the present invention include a cooling device for a semiconductor such as a CPU, which requires a higher cooling effect than that obtainable by natural convection. Utilizing the heat of vaporization may produce a superior effect to single-phase forced residual cooling, with the same coolant.

1. A heat exchanger to be used for cooling a semiconductor chip, comprising:
a first layer including a plurality of microchannels through which a coolant flows;
a second layer provided adjacent to said first layer, and including a supply path through which said coolant is supplied to said microchannel; and
a resistance unit that resists against a flow of said coolant from said supply path into said microchannel,
wherein a partition between said first layer and said second layer is constituted essentially of an elastic material.

2. The heat exchanger according to claim 1,
wherein said resistance unit includes:
a barrier wall formed at a connection interface between said supply path and said microchannel; and
said coolant is introduced from said second layer into said first layer through said connection interface.

3. The heat exchanger according to claim 1,
wherein said first layer is located in a lower portion of said heat exchanger, and said second layer is located in an upper portion thereof.

4. The heat exchanger according to claim 1,
wherein said microchannel includes a space delimited by an inner wall of said first layer formed in a thicknesswise direction from a bottom portion of said first portion and said elastic material, and said coolant flows in a predetermined direction through said microchannel.

5. A heat exchanger to be used for cooling a semiconductor chip, comprising:
a third layer including a plurality of microchannels through which a coolant flows;
a fourth layer provided adjacent to said third layer, and including a supply path through which said coolant is supplied to said microchannel; and
a nozzle that generates a leak flow of said coolant in a direction to accelerate a flow speed of said coolant through said microchannel.

6. The heat exchanger according to claim 5,
wherein said nozzle is formed on a partition between said third layer and said fourth layer with an inclination in a flowing direction of said coolant through said microchannel,
to thereby introduce said coolant from said fourth layer to said third layer through said connection interface between said supply path and said microchannel, and through said nozzle.

7. The heat exchanger according to claim 5,
wherein said third layer is located in a lower portion of said heat exchanger, and said fourth layer is located in an upper portion thereof.

8. The heat exchanger according to claim 5,
wherein said microchannel includes a space delimited by an inner wall of said first layer formed in a thicknesswise direction from a bottom portion of said first portion and a partition between said third layer and said fourth layer, and said coolant flows in a predetermined direction through said microchannel.

9. A heat exchanger to be used for cooling a semiconductor chip, comprising:
a fifth layer including a plurality of microchannels through which a coolant flows;
a sixth layer provided adjacent to said fifth layer, and from which a part of said coolant supplied to said microchannel flows out; and
a hole that allows said part of said coolant supplied to said microchannel to flow into said sixth layer.

10. The heat exchanger according to claim 9,
wherein said coolant is introduced from said fifth layer into said sixth layer, through said hole.

11. The heat exchanger according to claim 9,
wherein said fifth layer is located in a lower portion of said heat exchanger, and said sixth layer is located in an upper portion thereof.

12. The heat exchanger according to claim 9,
wherein said microchannel includes a space delimited by an inner wall of said first layer formed in a thicknesswise direction from a bottom portion of said first portion and a partition between said fifth layer and said sixth layer, and said coolant flows in a predetermined direction through said microchannel.

13. The heat exchanger according to claim 1,
further comprising an inlet located above said supply path, for introducing said coolant through said inlet.

14. A method of manufacturing a heat exchanger to be used for cooling a semiconductor chip, comprising:
forming a first layer including a plurality of microchannels through which a coolant flows;
forming a second layer adjacent to said first layer, so as to include a supply path through which said coolant is supplied to said microchannel;
forming a resistance unit that resists against a flow of said coolant from said supply path into said microchannel; and
forming a partition between said first layer and said second layer with an elastic material.

15. A method of manufacturing a heat exchanger to be used for cooling a semiconductor chip, comprising:
forming a third layer including a plurality of microchannels through which a coolant flows;
forming a fourth layer adjacent to said third layer, so as to include a supply path through which said coolant is supplied to said microchannel; and
forming a nozzle that generates a leak flow of said coolant in a direction to accelerate a flow speed of said coolant through said microchannel.

16. A method of manufacturing a heat exchanger to be used for cooling a semiconductor chip, comprising:
forming a fifth layer including a plurality of microchannels through which a coolant flows;
forming a sixth layer adjacent to said fifth layer, such that a part of said coolant supplied to said microchannel flows out of said sixth layer; and
forming a hole that allows said part of said coolant supplied to said microchannel to flow into said sixth layer.
